(19) United States
(12) Patent Application Publication
(10) Pub. No.: US 2015/0226777 A1
(43) Pub. Date: Aug. 13, 2015

(54) ANTENNA TESTING DEVICE AND METHOD

(71) Applicants: Fu Tai Hua Industry (Shenzhen) Co., Ltd., Shenzhen (CN); HON HAI PRECISION INDUSTRY CO., LTD., New Taipei (TW)

(72) Inventor: XIAN QIAN, Shenzhen (CN)

(21) Appl. No.: 14/564,768

(22) Filed: Dec. 9, 2014

(30) Foreign Application Priority Data
Feb. 12, 2014 (CN) 201410049239.8

(51) Int. Cl. G01R 29/10

(52) U.S. Cl. CPC G01R 29/10

(57) ABSTRACT

An antenna testing device includes a network analyzer and a coupling antenna connected to network analyzer. The network analyzer generates an incident wave at a preset frequency range. The coupling antenna receives the incident wave from the network analyzer and feeds back a testing reflected wave to the network analyzer based on induction effect between the coupling antenna and a test antenna. The network analyzer obtains testing voltage standing wave ratio (VSWR) of the coupling antenna according to the incident wave and the testing reflected wave and further determines whether radiation performance of the test antenna is normal according to the testing VSWR.

### FIELD

The subject matter herein generally relates to antenna testing devices and methods, and particularly to an antenna testing device and method used to test an antenna of a portable electronic device.

### BACKGROUND

In a typical method for testing of an antenna, the antenna is connected to a testing device such as a network analyzer by a wire or a cable. The network analyzer obtains radiation parameters such as voltage standing wave ratio (VSWR) of the antenna and determines whether radiation performance of the antenna is normal according to the radiation parameters. However, the wired connection may easily damage the antenna during testing. In addition, the antenna is commonly assembled inside a wireless communication device. Thus, it is inconvenient to connect the antenna inside the wireless communication device to the network analyzer by the wire or the cable.

### BRIEF DESCRIPTION OF THE DRAWINGS

Many aspects of the present disclosure can be better understood with reference to the drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is a block diagram of one embodiment of an antenna testing device.

FIG. 2 is a block diagram of another embodiment of an antenna testing device.

FIG. 3 is a flowchart illustrating one embodiment of a method for testing an antenna of a portable electronic device.

### DETAILED DESCRIPTION

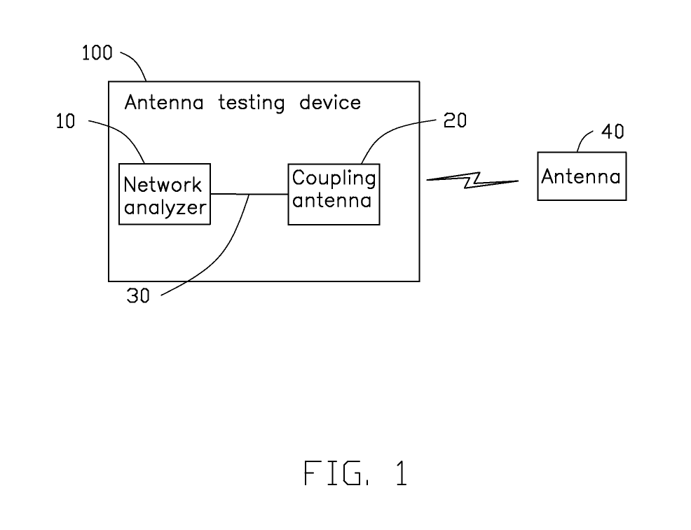

FIG. 1 is a block diagram of one embodiment of an antenna testing device 100. The antenna testing device 100 is used to test an antenna 40 of a portable electronic device such as a mobile phone. The antenna testing device 100 includes a network analyzer 10 and a coupling antenna 20. The network analyzer 10 is connected to the coupling antenna 20 by a data line 30 such as a radio frequency (RF) cable.

In test, the antenna 40 is placed in a position where the antenna 40 and the coupling antenna 20 are a preset distance apart. In this exemplary embodiment, the preset distance is less than or equal to 2 cm, preferably about 1 cm. The network analyzer 10 generates an incident wave at a preset frequency range. In this exemplary embodiment, the preset frequency range is about 700 MHz-2600 MHz. The coupling antenna 20 receives the incident wave from the network analyzer 10 and feeds back a testing reflected wave to the network analyzer 10. The network analyzer 10 obtains testing voltage standing wave ratio (VSWR) of the coupling antenna 20 based on the incident wave and the testing reflected wave.

Under the action of the incident wave, the coupling antenna 20 inducts with the antenna 40. Radiation impedance of the coupling antenna 20 is changed because of an induction effect between the coupling antenna 20 and the antenna 40 so that the testing reflected wave of the coupling antenna 20 is also correspondingly changed with the radiation impedance. Therefore, the testing reflected wave represents radiation performance of the antenna 40. The network analyzer 10 determines whether the radiation performance of the antenna 40 is normal according to the testing VSWR.

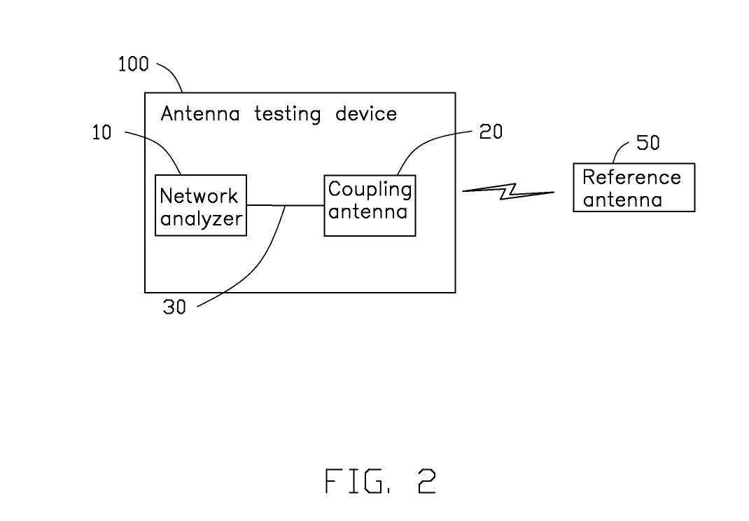

FIG. 2 illustrates the antenna testing device 100 further includes a reference antenna 50 defined as an antenna having a normal radiation performance. The reference antenna 50 is configured for obtaining a threshold value of reference VSWR. The network analyzer 10 determines whether the radiation performance of the antenna 40 is normal by comparing the testing VSWR to the reference VSWR. If the testing VSWR is within the threshold value of the reference VSWR, the radiation performance of the antenna 40 is normal. If the testing VSWR is beyond the threshold value of the reference VSWR, the radiation performance of the antenna 40 is abnormal.

Specifically, the reference antenna 50 is placed in the same position as the antenna 40. The network analyzer 10 generates the incident wave again. The coupling antenna 20 receives the incident wave from the network analyzer 10 and feeds back a reference reflected wave to the network analyzer 10. The network analyzer 10 obtains the threshold value of the reference VSWR based on the incident wave and the reference reflected wave.

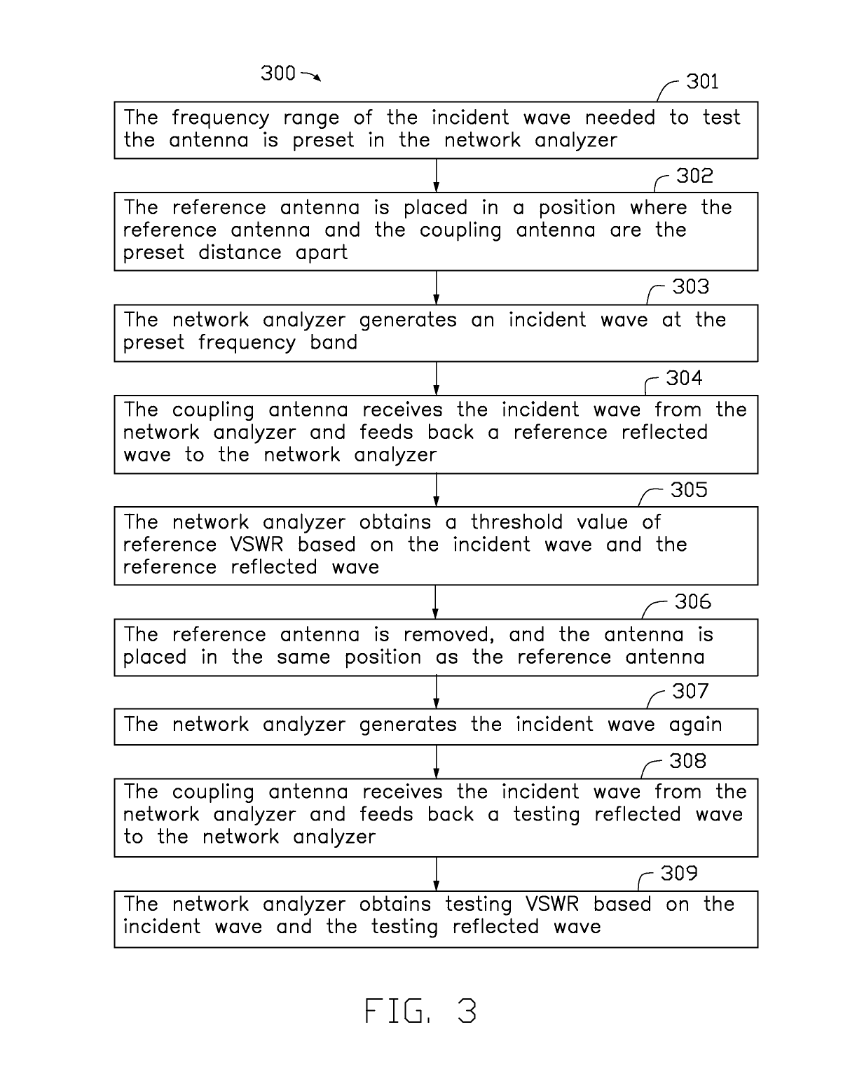

Referring to FIG. 3, a flowchart is presented in accordance with an example embodiment which is being thus illustrated. The example method 300 is provided by way of example, as there are a variety of ways to carry out the method. The method 300 described below can be carried out using the configurations illustrated in FIGS. 1 and 2, for example, and various elements of these figures are referenced in explaining example method 300. Each block shown in FIG. 3 represents one or more processes, methods or subroutines, carried out in the exemplary method 300. Additionally, the illustrated order of blocks is by example only and the order of the blocks can change according to the present disclosure. The exemplary method 300 can begin at block 301.

At block 301, the frequency range of the incident wave needed to test the antenna 40 is preset in the network analyzer 10. In this exemplary embodiment, the preset frequency range is about 700 MHz-2600 MHz.

At block 302, the reference antenna 50 is placed in a position where the reference antenna 50 and the coupling antenna 20 are the preset distance apart. In this exemplary embodiment, the preset distance is less than or equal to 2 cm, preferably about 1 cm.

At block 303, the network analyzer 10 is adjusted to generate the incident wave at the preset frequency band. In this exemplary embodiment, the incident wave is transmitted to the coupling antenna 20 by the data line 30.

At block 304, the coupling antenna 20 receives the incident wave from the network analyzer 10 and feeds back a reference reflected wave to the network analyzer 10. Under the action of the incident wave, the coupling antenna 20 inducts with the reference antenna 50. In this exemplary embodiment, radiation impedance of the coupling antenna 20 is changed because of induction effect between the coupling antenna 20 and the reference antenna 50 so that the reference reflected wave of the coupling antenna 20 is also correspondingly changed with the radiation impedance.

At block 305, the network analyzer 10 obtains a threshold value of reference VSWR based on the incident wave and the reference reflected wave.

At block 306, the reference antenna is removed, and the antenna 40 is placed in the same position as the reference antenna 50.

At block 307, the network analyzer 10 is adjusted to generate the incident wave again. In this exemplary embodiment, the incident wave is transmitted to the coupling antenna 20 by the data line 30.

At block 308, the coupling antenna 20 receives the incident wave from the network analyzer 10 and feeds back a testing reflected wave to the network analyzer 10. Under the action of the incident wave, the coupling antenna 20 inducts with the antenna 40. In this exemplary embodiment, radiation impedance of the coupling antenna 20 is changed because of induction effect between the coupling antenna 20 and the antenna 40 so that the reflected wave of the coupling antenna 20 is also correspondingly changed with the radiation impedance.

At block 309, the network analyzer 10 obtains testing VSWR based on the incident wave and the testing reflected wave. The network analyzer 10 determines whether the radiation performance of the antenna 40 is normal by comparing the testing VSWR with the threshold value of the reference VSWR. If the testing VSWR is within the threshold value of the reference VSWR, the radiation performance of the antenna 40 is normal. If the testing VSWR is beyond the threshold value of the reference VSWR, the radiation performance of the antenna 40 is abnormal.

The antenna testing device 100 can test the radiation performance of the antenna 40 without connecting the antenna 40 to other devices by wires or cables which is convenient. In addition, the antenna 40 may not be easily damaged during testing.

The embodiments shown and described above are only examples. Many details are often found in the art such as the other features. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. An antenna testing device comprising:
a network analyzer generating an incident wave at a preset frequency range; and
a coupling antenna connected to network analyzer, the coupling antenna receiving the incident wave from the network analyzer and feeding back a testing reflected wave to the network analyzer based on induction effect between the coupling antenna and a test antenna; wherein the network analyzer obtains testing voltage standing wave ratio (VSWR) of the coupling antenna according to the incident wave and the testing reflected wave and further determines whether radiation performance of the test antenna is normal according to the testing VSWR.

2. The antenna testing device of claim 1, wherein the network analyzer determines whether the radiation performance of the antenna is normal by comparing the testing VSWR to a threshold value of reference VSWR; if the testing VSWR is within the threshold value of the reference VSWR, the radiation performance of the antenna is normal; if the testing VSWR is beyond the threshold value of the reference VSWR, the radiation performance of the antenna is abnormal.

3. The antenna testing device of claim 2, further comprising a reference antenna, wherein the coupling antenna receives the incident wave from the network analyzer and feeds back a reference reflected wave to the network analyzer based on induction effect between the coupling antenna and the reference antenna; the network analyzer obtains the threshold value of the reference VSWR according to the incident wave and the reference reflected wave.

4. The antenna testing device of claim 1, wherein the frequency range of the incident wave is about 700 MHz to about 2600 MHz.

5. The antenna testing device of claim 3, wherein the test antenna and the reference antenna are placed in a same position where the test antenna and the reference antenna are apart from the coupling antenna a preset distance, the preset distance is less than or equal to 2 cm.

6. The antenna testing device of claim 5, wherein the preset distance is about 1 cm.

7. The antenna testing device of claim 1, wherein the coupling antenna is connected to the analyzer by a radio frequency cable.

8. An antenna testing method used to test an antenna, the antenna testing method comprising:
providing a network analyzer and a coupling antenna connected to the network analyzer;
generating an incident wave by the network analyzer;
transmitting the incident wave from the network analyzer to the coupling antenna;
feeding back a testing reflected wave from the coupling antenna to the networking analyzer based on induction effect between the coupling antenna and the antenna to be test;
obtaining testing voltage standing wave ratio (VSWR) of the coupling antenna according to the incident wave and the testing reflected wave; and
determining whether radiation performance of the antenna is normal according to the testing VSWR.

9. The antenna testing method of claim 8, further comprising:
obtaining a threshold value of reference VSWR; and
determining whether the radiation performance of the antenna is normal by comparing the testing VSWR with the threshold value of the reference VSWR; wherein if the testing VSWR is within the threshold value of the reference VSWR, the radiation performance of the antenna is normal; if the testing VSWR is beyond the threshold value of the reference VSWR, the radiation performance of the antenna is abnormal.

10. The antenna testing method of claim 8, wherein the step of obtaining a threshold value of reference VSWR comprises:
providing a reference antenna;
generating an incident wave by the network analyzer;
transmitting the incident wave from the network analyzer to the coupling antenna;
feeding back a reference reflected wave from the coupling antenna to the networking analyzer based on induction effect between the coupling antenna and the reference antenna; and
obtaining the threshold value of the reference VSWR according to the incident wave and the reference reflected wave.

11. The antenna testing method of claim 8, wherein the frequency range of the incident wave is about 700 MHz to about 2600 MHz.

12. The antenna testing method of claim 8, further comprising positioning the antenna to be tested and the reference antenna in a same position where the antenna to be test and the reference antenna are apart from the coupling antenna a preset distance before generating an incident wave by the network analyzer; wherein the preset distance is less than or equal to 2 cm.

13. The antenna testing method of claim 12, wherein the preset distance is about 1 cm.

14. An antenna testing device comprising:
a network analyzer generating an incident wave at a preset frequency; and
a coupling antenna connected to the network analyzer;
wherein, the coupling antenna receives the incident wave from the network analyzer and feeds back a test reflected wave to the network analyzer based on induction effect between the coupling antenna and a test antenna;
wherein, the network analyzer obtains voltage standing wave ration of the coupling antenna based on the incident wave and the test reflected wave from the test antenna; and
wherein, the test antenna radiation is determined based on the voltage standing wave ratio.

15. The antenna testing device of claim 14, wherein the network analyzer determines whether the radiation performance of the antenna is normal by comparing the testing VSWR to a threshold value of reference VSWR; if the testing VSWR is within the threshold value of the reference VSWR, the radiation performance of the antenna is normal; if the testing VSWR is beyond the threshold value of the reference VSWR, the radiation performance of the antenna is abnormal.

16. The antenna testing device of claim 15, further comprising a reference antenna, wherein the coupling antenna receives the incident wave from the network analyzer and feeds back a reference reflected wave to the network analyzer based on induction effect between the coupling antenna and the reference antenna; the network analyzer obtains the threshold value of the reference VSWR according to the incident wave and the reference reflected wave.

17. The antenna testing device of claim 14, wherein the frequency range of the incident wave is about 700 MHz to about 2600 MHz.

18. The antenna testing device of claim 17, wherein the test antenna and the reference antenna are placed in a same position where the test antenna and the reference antenna are apart from the coupling antenna a preset distance, the preset distance is less than or equal to 2 cm.

19. The antenna testing device of claim 18, wherein the preset distance is about 1 cm.

20. The antenna testing device of claim 14, wherein the coupling antenna is connected to the analyzer by a radio frequency cable.
